(19) United States
(12) Patent Application Publication
(10) Pub. No.: US 2006/0115958 A1
(43) Pub. Date: Jun. 1, 2006

(54) Method and apparatus for forming buried oxygen precipitate layers in multi-layer wafers

(76) Inventors: Jason W. Weigold, Somerville, MA (US); Thomas D. Chen, Cambridge, MA (US); Denis Mel O'Kane, Medford, MA (US); David J. Collins, Fairport, NY (US); Andrew D. Bain, Adare (IE)

Correspondence Address: BROMBERG & SUNSTEIN LLP, 125 SUMMER STREET, BOSTON, MA, 02110-1618, US

(21) Appl. No.: 11/262,303

(22) Filed: Oct. 28, 2005

Related U.S. Application Data
(60) Provisional application No. 60/630,058, filed on Nov. 22, 2004.

(51) Int. Cl. H01L 21/84; H01L 21/30

(52) U.S. Cl. 438/455; 438/459; 438/149

(57) ABSTRACT

A method of forming a SOI wafer obtains an intermediate apparatus having a first wafer, a second wafer, and an insulator material bonding the first and second wafers together. The first wafer has an oxygen precipitate concentration sufficient for gettering. The method reduces the profile of at least a portion of the first wafer to form an exposed surface, and adds a layer of material to the exposed surface of the first wafer. The layer of material substantially integrates with the first wafer to have substantially the same structure.

### PRIORITY

This patent application claims priority from provisional U.S. patent application No. 60/630,058, filed Nov. 22, 2004, entitled, “METHOD AND APPARATUS FOR FORMING BURIED OXYGEN PRECIPITATE LAYERS IN MULTI-LAYER WAFERS,” and naming Jason W. Weigold, Thomas D. Chen, Denis Mel O'Kane, David J. Collins, and Andrew D. Bain as inventors, the disclosure of which is incorporated herein, in its entirety, by reference.

### FIELD OF THE INVENTION

The invention generally relates to integrated circuits and, more particularly, the invention relates to minimizing the impact of impurities in integrated circuits.

### BACKGROUND OF THE INVENTION

Impurities and defects in the silicon of an integrated circuit can significantly degrade device performance. For example, impurities and defects within integrated circuits having active circuitry can adversely affect gate oxide integrity, minority carrier lifetime, and leakage current. To minimize their impact, silicon-based devices often have internal gettering sites to collect impurities at a local, substantially innocuous area.

Some types of devices, such as those implemented on silicon-on-insulator wafers (“SOI wafers”), often cannot benefit from various types of gettering sites. Specifically, SOI wafers have an insulator layer positioned between a top layer having active circuitry and/or MEMS devices, and a bottom layer. Often, the bottom layer has gettering sites. Because the insulator layer acts as a barrier between the other two layers, however, the top layer cannot benefit from those remote gettering sites.

Gettering of SOI wafers therefore is difficult.

### SUMMARY OF THE INVENTION

In accordance with one aspect of the invention, a method of forming a SOI wafer obtains an intermediate apparatus having a first wafer, a second wafer, and an insulator material bonding the first and second wafers together. The first wafer has an oxygen precipitate concentration sufficient for gettering. The method reduces the profile of at least a portion of the first wafer to form an exposed surface, and adds a layer of material to the exposed surface of the first wafer. The layer of material substantially integrates with the first wafer to have substantially the same structure.

In some embodiments, the layer of material has a negligible concentration of oxygen precipitates. The concentration of oxygen precipitates in first wafer illustratively may be greater than this negligible concentration of oxygen precipitate. For example, the gettering may be sufficient to form operable active circuitry on the layer of material. Among other things, the first wafer and material may be formed from silicon. Moreover, the oxygen precipitates in the first wafer may be distributed substantially uniformly.

The SOI wafer may be obtained a number of ways. For example, it may be obtained by bonding the first wafer to the second wafer via the insulator with a bond anneal. The bond anneal forms oxygen precipitates within the first wafer. The first wafer may have a specified concentration of oxygen prior to the bond anneal. As an example, this specified concentration of oxygen may be on the order of greater than or equal to about 6.7×10¹⁷ cm⁻³.

In accordance with another aspect of the invention, a MEMS device has a SOI wafer with a first layer having a working portion, a second layer, and an insulator layer between the first and second layer. The first layer also has a gettering portion between the working portion and the insulator layer. The gettering portion has an oxygen precipitate concentration that is greater than the oxygen precipitate concentration of the working portion. In addition, the gettering portion provides a gettering effect to the working portion. The MEMS device also has movable structure formed at least on the working portion.

In illustrative embodiments, the SOI wafer has a standard profile. Moreover, in addition to (or instead of) having movable structure, the working portion also may have circuitry. Some embodiments position the gettering portion, which can be elongated in two dimensions, between the working portion and the entire insulator layer.

### BRIEF DESCRIPTION OF THE DRAWINGS

The foregoing advantages of the invention will be appreciated more fully from the following further description thereof with reference to the accompanying drawings wherein:

FIG. 1A schematically shows an integrated circuit that may be produced in accordance with illustrative embodiment of the invention.

FIG. 1B schematically shows a plan view of the wafer/integrated circuit shown in FIG. 1A.

FIG. 2 shows a process of forming an integrated circuit in accordance with illustrative embodiments of the invention.

FIG. 3A schematically shows a bulk wafer prior to being bonded with another bulk wafer (corresponds to step 200 of FIG. 2).

FIG. 3B schematically shows a multilayer wafer formed by bonding the bulk wafers shown in FIG. 3A (corresponds to step 200 of FIG. 2).

FIG. 3C schematically shows the multilayer wafer of FIG. 3B after its profile has been reduced (corresponds to step 202 of FIG. 2).

FIG. 3D schematically shows the reduced profile wafer of FIG. 3C after an additional layer has been formed on its top surface (corresponds to step 204 of FIG. 2).

FIG. 3E schematically shows the wafer of FIG. 3D after structure and circuitry are added to its top surface (corresponds to steps 206 and 208 of FIG. 2).

### DESCRIPTION OF ILLUSTRATIVE EMBODIMENTS

Illustrative embodiments of the invention facilitate use of multilayer wafers by forming a topside working layer with a concentration of contaminants that is low enough to form either or both circuitry and MEMS structure. To do this, a layer beneath the working layer has an oxygen precipitate concentration that is sufficient for gettering the working layer. This gettering effectively mitigates the contaminant concentration of the noted topside working layer, thus permitting the circuitry and/or structure formation. Details of illustrative embodiments are discussed below.

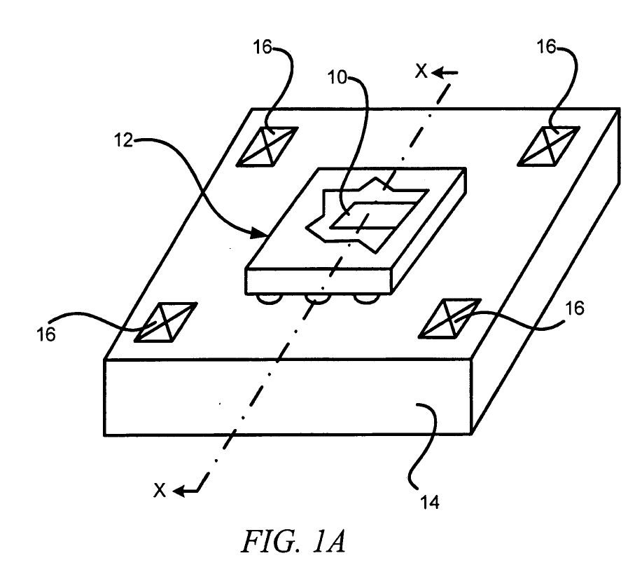

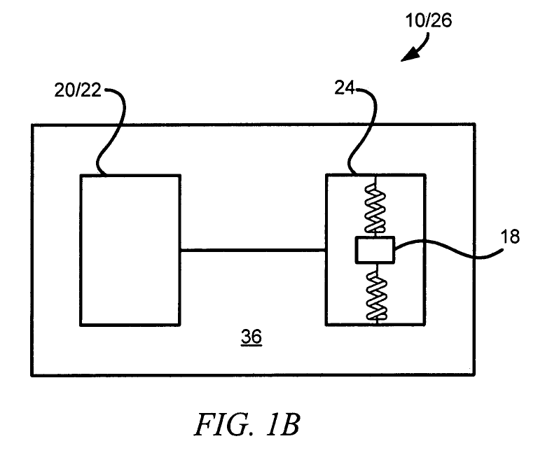

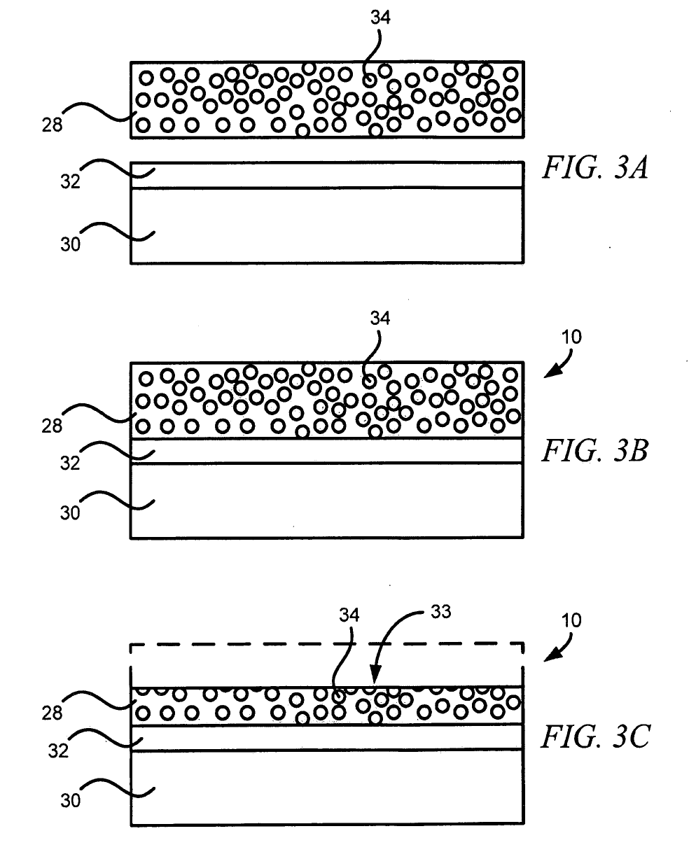

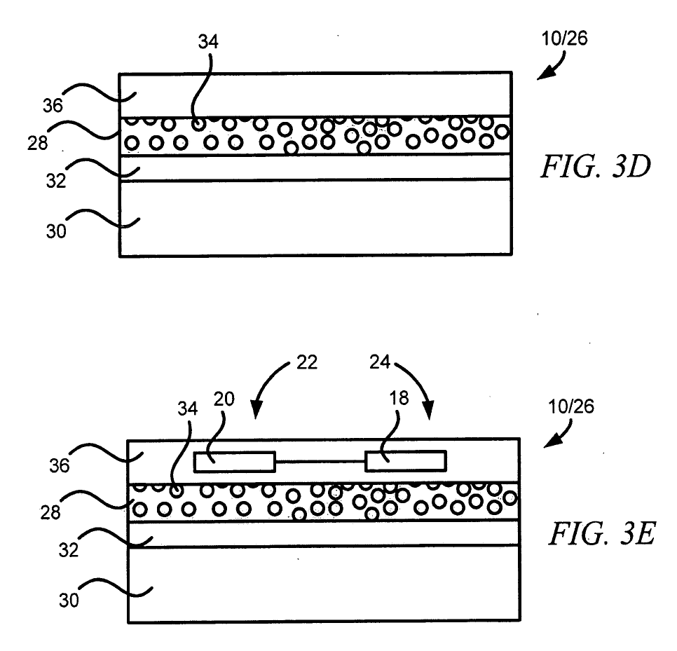

FIG. 1A schematically shows an exemplary packaged integrated circuit chip (referred to herein as “integrated circuit 10” or “chip 10”) that may be produced in accordance with illustrative embodiments of the invention. Specifically, the integrated circuit 10 in this embodiment is a MEMS device having both movable structure 18 and circuitry 20 (see FIGS. 1B and 3E, discussed below). The integrated circuit 10 illustratively is formed on a silicon-on-insulator wafer (“SOI,” shown in cross-section in subsequent figures) and packaged within a conventional package 12 (e.g., a ceramic or premolded package). The package 12 is coupled with a circuit board 14 having interconnects 16 to electrically communicate with an external device, such as a computer.

If implemented as a MEMS device, the integrated circuit 10 may execute any conventionally known functionality commonly implemented on a MEMS device, such as an inertial sensor. For example, the integrated circuit 10 may be a gyroscope or an accelerometer. Exemplary MEMS gyroscopes are discussed in greater detail in U.S. Pat. No. 6,505,511, which is assigned to Analog Devices, Inc. of Norwood, Mass. Exemplary MEMS accelerometers are discussed in greater detail in U.S. Pat. No. 5,939,633, which also is assigned to Analog Devices, Inc. The disclosures of U.S. Pat. Nos. 5,939,633 and 6,505,511 are incorporated herein, in their entireties, by reference.

Although the integrated circuit 10 is discussed as a MEMS inertial sensor, principles of illustrative embodiments can apply to other integrated circuits, such as pressure sensors and microphones (e.g., MEMS pressure sensors or MEMS microphones). Accordingly, discussion of an inertial sensor is exemplary and not intended to limit the scope of various embodiments of the invention.

It also should be noted that discussion of MEMS devices is exemplary. Accordingly, principles of illustrative embodiments may apply to other types integrated circuits, such as those having no structure 18. It also should be noted that discussion of a packaged integrated circuit also is for illustrative purposes only. For example, instead of or in addition to being within a package 12, the integrated circuit 10 could be capped.

FIG. 1B schematically shows a plan view of the integrated circuit 10 of FIG. 1A formed in accordance with illustrative embodiments of the invention. Specifically, the integrated circuit 10 in this embodiment includes movable MEMS structure 18, and circuitry 20 for actuating and detecting movement of the structure 18. The structure 18 and circuitry 20 in this embodiment are located in two separate regions; namely, a circuit region 22 having circuitry 20, and a structure region 24 having MEMS structure 18. In some embodiments, however, the structure and circuit regions 24 and 22 may have overlapping footprints.

If the integrated circuit 10 implements a gyroscope, for example, the circuitry 20 may have actuation components for oscillating a movable mass, and detection components for detecting mass movement. Although the structure 18 and circuitry 20 are shown schematically, they may be similar to corresponding components known by those skilled in the art. For example, such structure 18 and circuitry 20 may be similar to those disclosed in the incorporated patents.

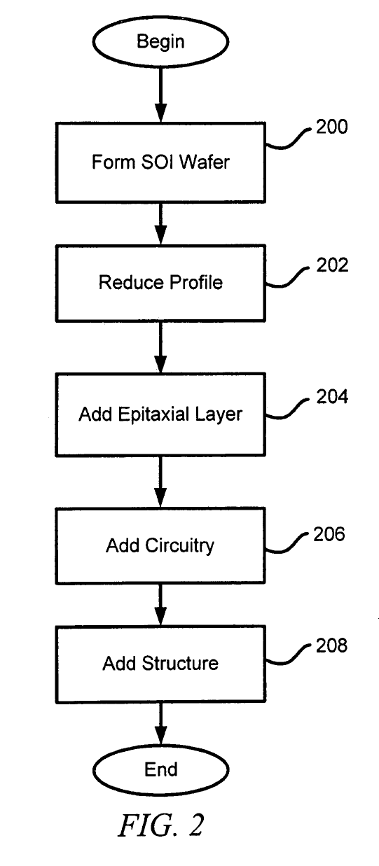

FIG. 2 shows a process of forming an integrated circuit 10 in accordance with illustrative embodiments of the invention. FIGS. 3A-3E correspondingly show the integrated circuit 10 at various stages of development of this process described in FIG. 2. Accordingly, FIGS. 3A-3E are discussed in conjunction with FIG. 2.

The process begins at step 200, which forms a multilayer wafer 26. As discussed above, in illustrative embodiments, the multilayer wafer 26 is a silicon-on-insulator wafer (“SOI wafer 26”). In alternative embodiments, however, other types of bonded wafers may be used.

This step may be executed in accordance with conventional processes. To that end, as shown in FIG. 3A (before the SOI wafer 26 is formed), the SOI wafer 26 has a top layer 28 formed from a bulk silicon wafer, and a bottom layer 30 that also is formed from a bulk silicon wafer. The two bulk wafers may be formed by conventional processes, such as those implementing conventional Czochralski crystal growth processes. Before the two wafers are bonded, the bulk silicon wafer forming the bottom layer 30 has a layer of insulator (“insulator layer 32”) substantially uniformly distributed along its top surface. In alternative embodiments, the bottom surface of the top layer 28 has the layer of insulator. In yet other embodiments, both the top and bottom surfaces of the bottom and top layers 30 and 28, respectively, may have the insulator. Among other things, the insulator layer 32 may be a deposited or grown oxide.

Conventional thermal anneal processes bond the top and bottom layers 28 and 30 together (see FIG. 3B). As known by those skilled in the art, thermal anneal processes are performed at temperatures that are sufficiently high to effectively bond the top and bottom layers 28 and 30 together via the insulator layer 32. At this stage of the process, the SOI wafer 26 may be referred to as an “intermediate apparatus.”

The silicon wafer forming the top layer 28 illustratively is specified to have an oxygen concentration that, after it is subjected to the high temperature anneal operations, should produce oxygen precipitates that adequately getter subsequently added layers (discussed below). For example, a bulk silicon wafer having an oxygen concentration of greater than or equal to about 6.7×10¹⁷ cm⁻³ may produce satisfactory results when subjected to some commonly used anneal temperatures. It nevertheless should be noted that other concentrations should suffice, depending upon the anneal temperature.

FIGS. 3A-3E schematically show oxygen and oxygen precipitates as circles identified by reference number 34 within the top layer 28. In various embodiments, the oxygen precipitates 34 in the top layer 28 are substantially uniformly distributed in at least two dimensions within the top layer 28. Accordingly, as discussed below, this arrangement of oxygen precipitates 34 effectively forms a gettering site that is elongated in at least two dimensions. For example, those two dimensions can be the length and width of the top layer 28.

The method then continues to step 202, which reduces the profile (i.e., thickness) of the entire SOI wafer 26. To that end, conventional grinding techniques reduce thickness of the top layer 28 to form of a new top surface 33. In alternative embodiments, the bottom layer thickness also may be reduced. This reduced thickness may be dictated by the intended use of they ultimately produced integrated circuit 10. In illustrative embodiments, the profile is reduced to have a thickness that is less than that of standard wafer. FIG. 3C schematically shows the removed portion of the top layer 28 in phantom.

After it reduces the profile of the SOI wafer 26, the method then adds an additional layer 36 to the new top surface 33 of the top layer 28 (step 204). FIG. 3D schematically shows the SOI wafer 26 at this point in the process.

More specifically, illustrative embodiments grow an epitaxial layer (also identified by reference number 36 because it is the additional layer 36) on the new top surface 33 of the top layer 28, thus forming the additional layer 36. Among other things, the epitaxial layer 36 illustratively is grown from the same type of material making up the top layer 28; namely, silicon in this embodiment. The epitaxial layer 36 effectively integrates with the top layer 28 of the SOI wafer 26 to form a substantially unitary layer above the insulator layer 32.

As known by those skilled in the art, an epitaxial layer formed in this manner should have a crystal structure that substantially reproduces the crystal structure of the top layer 28 of the SOI wafer 26. Despite this, the epitaxial layer 36 has other physical properties that are different than that of the top layer 28. In particular, the epitaxial layer 36 is substantially free of oxygen precipitates 34. More specifically, the epitaxial layer 36 may have a negligible oxygen precipitate concentration, which has a negligible impact on structure 18 and/or circuitry 20 (e.g., active circuitry) formed within or on it.

After the method forms the additional layer 36, the overall apparatus illustratively has a substantially standard profile for use in conventional semiconductor processes. In alternative embodiments, however, the overall apparatus may have a non-standard profile.

At this point in the process, the method may add circuitry 20, MEMS structure 18, or both (steps 206 and 208, and FIG. 3E) to the additional layer 36. The area forming the circuitry 20 and/or structure 18 may be referred to as a “working portion.” It should be noted that although steps 206 and 208 are in the order shown, they may be executed in a different order, or at substantially the same time.

Accordingly, the top layer 28 of the SOI wafer 26 effectively forms a substantially uniform gettering site for gettering metal impurities in the additional layer 36. As known by those skilled in the art, such a gettering site should have the ability to retain metal impurities, among other impurities, during and after device formation. As also known by those skilled in the art, some metals may release from the gettering site if heated to a sufficiently high temperature. When cooled, however, the gettering site should again re-retain the released metals. In illustrative embodiments, fabrication processes form the integrated circuit 10 by means of a plurality of heating steps. The heating steps at the latter stages of the fabrication process, however, illustratively are cooler than those at the earlier stages, thus facilitating gettering.

To ensure that the ultimate oxygen precipitate concentration would not interfere with subsequently formed circuitry 20 and/or structure 18, known related prior art processes require the top layer wafers to have a low oxygen concentration. This increases the cost of the overall SOI wafer 26. Integrated circuits implementing illustrative embodiments thus can take advantage of the high oxygen concentration that naturally forms within wafers during conventional Czochralski crystal production processes. As noted above, this oxygen concentration ultimately produces a relatively large gettering site buried beneath the epitaxial layer 36. Accordingly, illustrative embodiments can use lower cost, oxygen rich wafers to form the top layer 28.

Although the above discussion discloses various exemplary embodiments of the invention, it should be apparent that those skilled in the art can make various modifications that will achieve some of the advantages of the invention without departing from the true scope of the invention.

What is claimed is:

1. A method of forming a SOI wafer, the method comprising:
obtaining an intermediate apparatus comprising a first wafer, a second wafer, and an insulator material bonding the first and second wafers together, the first wafer having an oxygen precipitate concentration sufficient for gettering;
reducing the profile of at least a portion of the first wafer to form an exposed surface; and
adding a layer of material to the exposed surface of the first wafer, the layer of material substantially integrating with the first wafer to have substantially the same structure.

2. The method as defined by claim 1 wherein the layer of material has a negligible concentration of oxygen precipitates, the concentration of oxygen precipitates in the first wafer being greater than the negligible oxygen precipitate concentration.

3. The method as defined by claim 1 wherein the gettering is sufficient to form operable active circuitry on the layer of material.

4. The method as defined by claim 1 wherein the first wafer is formed from silicon.

5. The method as defined by claim 1 wherein obtaining comprises:
bonding the first wafer to the second wafer via the insulator with a bond anneal, the bond anneal forming oxygen precipitate within the first wafer.

6. The method as defined by claim 5 wherein the first wafer has a concentration of oxygen prior to the bond anneal, the concentration of oxygen prior to the bond anneal being greater than or equal to about 6.7×10¹⁷ cm⁻³.

7. The method as defined by claim 1 wherein the first wafer and layer of material are formed from substantially the same material.

8. The method as defined by claim 1 wherein the oxygen precipitates in the first wafer are distributed substantially uniformly.

9. The apparatus formed by the process defined by claim 1.

10. A MEMS device comprising:
a SOI wafer comprising a first layer, a second layer, and an insulator layer between the first and second layers, the first layer having a working portion,
the first layer also having a gettering portion between the working portion and the insulator layer, the gettering portion having an oxygen precipitate concentration that is greater than the oxygen precipitate concentration of the working portion, the gettering portion providing a gettering effect to the working portion; and
movable structure formed at least on the working portion.

11. The MEMS device as defined by claim 10 wherein the SOI wafer has a substantially standard profile.

12. The MEMS device as defined by claim 10 wherein the working portion includes circuitry.

13. The MEMS device as defined by claim 10 wherein the gettering portion is between the working portion and the entire insulator layer.

14. The MEMS device as defined by claim 10 wherein the gettering portion is elongated in two dimensions.

15. The MEMS device as defined by claim 10 wherein the oxygen precipitates in the gettering portion are distributed substantially uniformly.

16. An apparatus comprising:
a SOI wafer comprising a first layer, a second layer, and an insulator layer between the first and second layer, the first layer having a working portion,
means for gettering the working portion, the gettering means being between the working portion and the insulator layer, the gettering means having an oxygen precipitate concentration that is greater than the oxygen precipitate concentration of the working portion, the gettering means providing a gettering effect to the working portion.

17. The apparatus as defined by claim 16 further including movable structure formed at least on the working portion.

18. The MEMS device as defined by claim 16 wherein the working portion includes circuitry.

19. The MEMS device as defined by claim 16 wherein the gettering means is elongated in two dimensions.

20. The MEMS device as defined by claim 16 wherein the oxygen precipitates in the gettering means are distributed substantially uniformly.
